(19) United States
(12) Patent Application Publication
(10) Pub. No.: US 2013/0023127 A1
(43) Pub. Date: Jan. 24, 2013

(54) METHOD OF FORMING A CONTACT HOLE AND APPARATUS FOR PERFORMING THE SAME

(71) Applicants: Chong-Kwang CHANG, Incheon (KR); Young-Mook OH, Hwaseong-si (KR); Jung-Hoon LEE, Suwon-si (KR); Hak-Yoon AHN, Seoul (KR)

(72) Inventors: Chong-Kwang CHANG, Incheon (KR); Young-Mook OH, Hwaseong-si (KR); Jung-Hoon LEE, Suwon-si (KR); Hak-Yoon AHN, Seoul (KR)

(21) Appl. No.: 13/476,381

(22) Filed: May 21, 2012

(30) Foreign Application Priority Data
Jul. 22, 2011 (KR) 10-2011-0072808

(51) Int. Cl. H01L 21/3065; C23F 1/08

(52) U.S. Cl. 438/711; 156/345.38; 257/E21.218

(57) ABSTRACT

A method of forming a contact hole includes loading a substrate into a plasma chamber, the substrate including an etch stop layer, an insulation interlayer, a mask layer and a photoresist pattern sequentially disposed thereon, applying a DC voltage to an upper electrode and applying a first high frequency power and a second high frequency power to a lower electrode to generate plasma in the chamber, the first frequency power and second high frequency powers having different frequency levels, supplying a reaction gas to the chamber to etch the mask layer and the insulation interlayer, wherein the chamber is maintained at a temperature of 100° C. to 200° C.; and etching the etch stop layer to form a contact hole

### CROSS-REFERENCE TO RELATED APPLICATION

Korean Patent Application No. 2011-72808, filed on Jul. 22, 2011 in the Korean Intellectual Property Office (KIPO) and entitled “METHOD OF FORMING A CONTACT HOLE AND APPARATUS FOR PERFORMING THE SAME” is hereby incorporated herein by reference in its entirety.

### BACKGROUND

Example embodiments relate to a method of forming a contact hole and a plasma etching apparatus for performing the same. More particularly, example embodiments relate to a method of forming a contact hole having a width below 40 nm and a plasma etching apparatus for performing the same.

### SUMMARY

According to an embodiment, a method of forming a contact hole includes loading a substrate into a plasma chamber, the substrate including an etch stop layer, an insulation interlayer, a mask layer and a photoresist pattern sequentially disposed thereon, applying a DC voltage to an upper electrode and applying a first high frequency power and a second high frequency power to a lower electrode to generate plasma in the chamber, the first frequency power and second high frequency powers having different frequency levels, supplying a reaction gas to the chamber to etch the mask layer and the insulation interlayer, wherein the chamber is maintained at a temperature of 100° C. to 200° C., and etching the etch stop layer to form the contact hole.

A focus ring may be provided to surround the substrate loaded in the chamber. The focus ring may include a ring of silicon and a polymer sheet.

The first high frequency power may be 30 MHz to 50 MHz and the second high frequency power may be 1 to 20 MHz.

The reaction gas for etching the mask layer and the insulation interlayer may include a CFₓ gas or a CₓH_{y}F_{z} gas. The reaction gas for etching the mask layer and the insulation interlayer may further include at least one dilution gas selected from oxygen, nitrogen, hydrogen, CO and CO₂.

Etching the mask layer and the insulation interlayer may include maintaining the chamber under a pressure of 1 to 1000 mTorr.

The method may further include performing an ashing process to remove the mask layer after etching the insulation interlayer.

Etching of mask layer and the insulation interlayer may include maintaining plasma in the chamber to have a plasma density of 3.0E10 to 13.0E10 cm ⁻³.

Etching of mask layer and the insulation interlayer may include applying a DC voltage of 300V to 1800V to the upper electrode.

According to an embodiment, there is provided a plasma etching apparatus including a chamber, an upper electrode provided in an upper portion of the chamber, a DC power source connected to the upper electrode, a gas supply unit configured to supply an etching gas to the chamber, a lower electrode provided in a lower portion of the chamber under the upper electrode, a first high frequency power source connected to the lower electrode to apply a first high frequency power, a second high frequency power source connected to the lower electrode to apply a second high frequency power having a different frequency level from the first high frequency power and a temperature controller configured to maintain the chamber at a temperature of 100° C. to 200° C.

The plasma etching apparatus may further include a focus ring surrounding a substrate loaded on the lower electrode, the focus ring including a ring of silicon and a polymer sheet.

The focus ring may include an upper ring of silicon and a lower ring of silicon. The polymer sheet may be between the upper ring and the lower ring.

According to an embodiment, there is provided a method of forming a contact hole, the method including loading a substrate onto a lower electrode inside a plasma chamber such that the substrate is surrounded by a focus ring, the substrate including an etch stop layer, an insulation interlayer, a mask layer and a photoresist pattern sequentially disposed thereon, the photoresist pattern including openings having a width of less than 40 nm, and the focus ring including a ring of silicon and a polymer sheet attached to the ring of silicon, and carrying out a first etching process to etch the mask layer, the first etching process including applying a first DC voltage to an upper electrode and applying a first high frequency power and a second high frequency power simultaneously to the lower electrode to generate plasma in the chamber, the first high frequency power and the second high frequency power having different frequency levels from each other, and supplying a reaction gas to the chamber to etch the mask layer, using the photoresist pattern as an etching mask of the first etching process, to form a mask layer pattern, while maintaining sidewalls of the chamber at a temperature of 100° C. to 200° C.

The method may further include carrying out a second etching process inside the plasma chamber, after the first etching process. The second etching process may include applying a second DC voltage to the upper electrode and applying a third high frequency power and a fourth high frequency power simultaneously to the lower electrode to generate plasma in the chamber, the third high frequency power and the fourth high frequency power having different frequency levels from each other, and supplying a reaction gas to the chamber to etch the insulation layer using the mask layer pattern as an etching mask of the second etching process, to form an insulation layer pattern and to remove the photoresist pattern and at least a portion of the mask layer pattern, while maintaining sidewalls of the chamber at a temperature of 100° C. to 200° C.

The method may further include carrying out a third etching process inside the plasma chamber, after the second etching process. The third etching process may include applying a third DC voltage to the upper electrode and applying a fifth high frequency power and a sixth high frequency power simultaneously to the lower electrode to generate plasma in the chamber, the fifth high frequency power and the sixth high frequency power having different frequency levels from each other, and supplying a reaction gas to the chamber to etch the etch stop layer using the insulation layer pattern as an etching mask of the third etching process, while maintaining sidewalls of the chamber at a temperature of 100° C. to 200° C.

The mask layer may include an amorphous carbon layer adjacent to the insulation layer and a silicon oxynitride layer on the amorphous carbon layer. The mask layer pattern formed in the first etching process may include a silicon oxynitride layer pattern and an amorphous carbon layer pattern. The second etching process may remove the oxynitride layer pattern. The method may further include an ashing process inside the process chamber after the second etching process and before the third etching process, the ashing process including applying a fourth DC voltage to the upper electrode and applying a seventh high frequency power and a eighth high frequency power simultaneously to the lower electrode to generate plasma in the chamber, the seventh high frequency power and the eighth high frequency power having different frequency levels from each other, and supplying oxygen to the chamber to remove the amorphous carbon layer, while maintaining sidewalls of the chamber at a temperature of 100° C. to 200° C.

### BRIEF DESCRIPTION OF THE DRAWINGS

Features will become apparent to those of ordinary skill in the art by describing in detail exemplary embodiments with reference to the attached drawings in which:

FIG. 1 illustrates a cross-sectional view of a plasma etching apparatus in accordance with an example embodiment.

FIGS. 2A and 2B illustrate a perspective view and a cross-sectional view of an example of a focus ring included in the plasma etching apparatus in FIG. 1.

FIGS. 3A and 3B illustrate a perspective view and a cross-sectional view of another example of a focus ring included in the plasma etching apparatus in FIG. 1.

FIGS. 4 to 9 illustrate cross-sectional views of stages of a method of forming a contact hole in accordance with an example embodiment.

FIG. 10 illustrates a graph showing widths of contact holes versus substrate radius according to Example Embodiment and Comparative Example.

### DETAILED DESCRIPTION

Example embodiments will now be described more fully hereinafter with reference to the accompanying drawings; however, they may be embodied in different forms and should not be construed as limited to the embodiments set forth herein.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

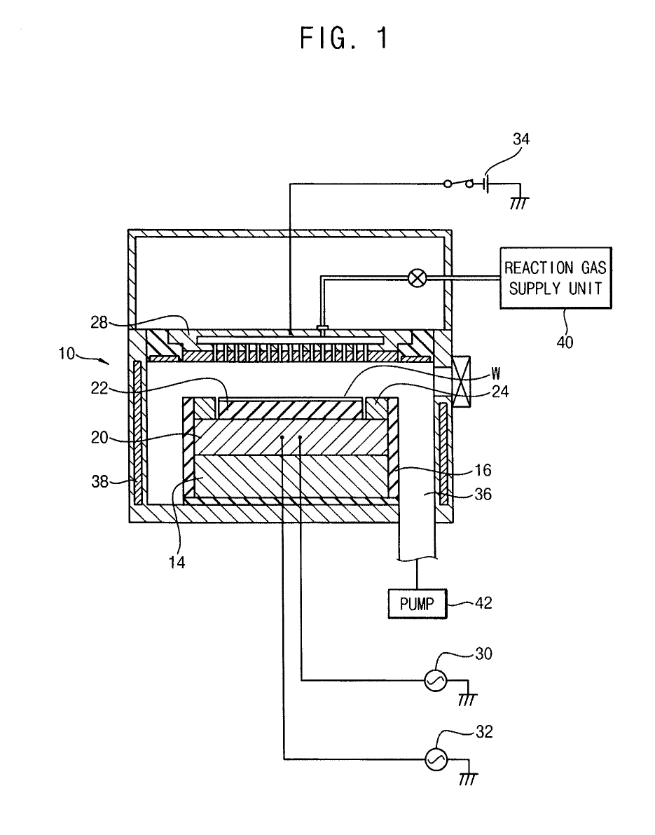

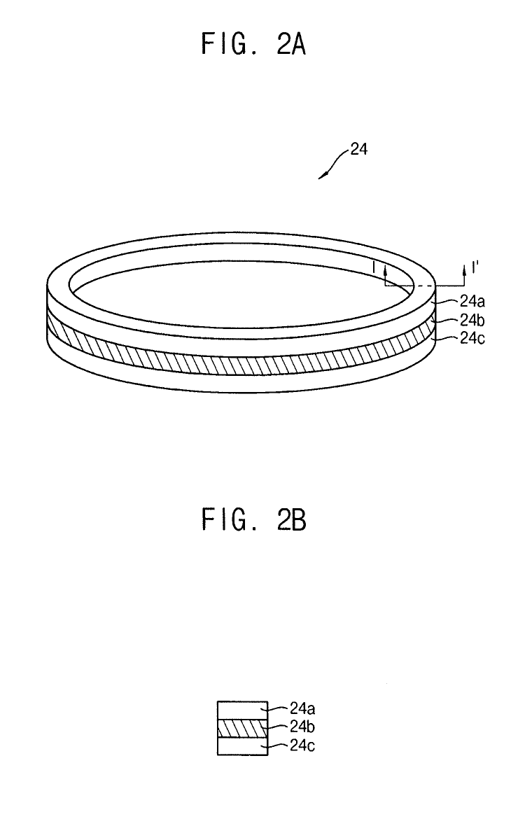

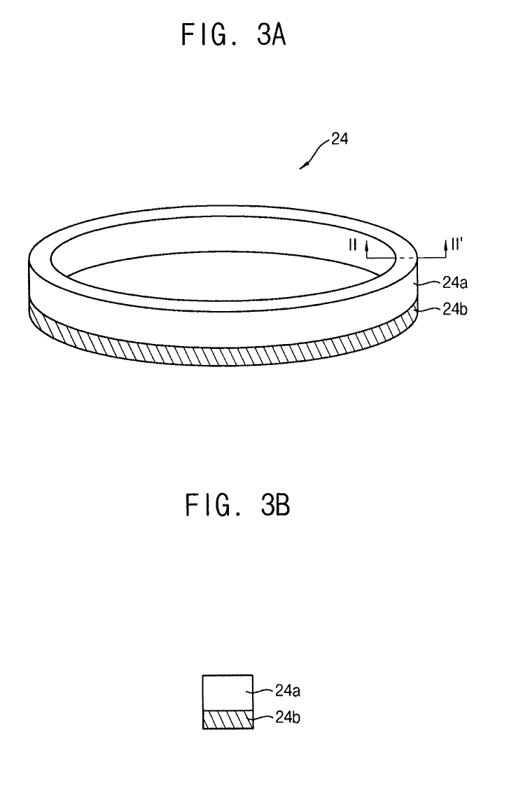

FIG. 1 is a cross-sectional view illustrating a plasma etching apparatus in accordance with an example embodiment. FIGS. 2A and 2B are a perspective view and a cross-sectional view, respectively, illustrating an example of a focus ring included in the plasma etching apparatus in FIG. 1. FIGS. 3A and 3B are a perspective view and a cross-sectional view, respectively, illustrating another example of a focus ring included in the plasma etching apparatus in FIG. 1.

Referring to FIG. 1, a plasma etching apparatus according to an example embodiment may include a susceptor 20 including a lower electrode within a chamber 10, an electrostatic chuck 22 provided on the susceptor 20, a focus ring 24 provided on the susceptor 20 to surround the electrostatic chuck 22, an upper electrode 28, first and second high frequency power sources 30, 32 for applying high frequency power to the susceptor 20, a DC power source 34 for applying a DC voltage to the upper electrode 28, an exhaust port 36, and a temperature controller 38 for controlling a temperature of a sidewall of the chamber 10.

The chamber 10 may be formed of an anodic oxidized aluminum material. A susceptor base 14 may be provided to support the susceptor 20 in the chamber 10.

A semiconductor substrate (W) may be loaded onto the electrostatic chuck 22 on the susceptor 20. The electrostatic chuck 22 may hold the semiconductor substrate (W) using an electrostatic force.

A cylindrical sidewall member 16 may be provided to surround the susceptor 20 and the susceptor base 14. The sidewall member 16 may include quartz. A cooling chamber (not illustrated) may be provided within the susceptor base 14 to circulate a refrigerant liquid of a predetermined temperature to thereby control the temperature of the semiconductor substrate (W).

The focus ring 24 may be provided to surround the semiconductor substrate (W). In the absence of the focus ring 24, the etching rate in the middle region of the semiconductor substrate (W) may be greater or less than the etching rate in the peripheral region of the semiconductor substrate (W). The focus ring 24 may be provided to thereby improve the etching uniformity in the substrate.

The focus ring 24 may include a polymer sheet that is attached to the ring of silicon. The polymer sheet may include carbon and fluorine.

Referring to FIGS. 2A and 2B, the focus ring 24 may include a polymer sheet 24b between an upper ring 24a and a lower ring 24c of silicon. In another example, as illustrated in FIGS. 3A and 3B, the focus ring 24 may include a polymer sheet that is attached to a lower surface of an upper ring 24a of silicon.

When the focus ring 24 includes the polymer sheet 24b, the heat conductivity of the focus ring 24 may be increased. Accordingly, the temperature of the focus ring 24 may be controlled uniformly around the entire focus ring 24, and thus, the etching uniformity in the peripheral region of the semiconductor substrate (W) may be improved. As mentioned above, the material of the focus ring 24 may be selected to control the temperature distribution of the focus ring 24 to be uniform and to prevent an unwanted temperature rise of the focus ring 24. Accordingly, in the etching apparatus according to the present embodiment, the focus ring 24 may not be affected by the temperature rise of the sidewall of the chamber 10.

The upper electrode 28 may be provided above the susceptor 20. Plasma may be generated between the upper electrode 28 and the lower electrode (that is, the susceptor 20) to etch a thin layer on the semiconductor substrate. The upper electrode 28 may include an electrode plate having a plurality of outlets and an electrode supporting member. Reaction gases may be supplied into the chamber 10 through the outlets.

A reaction gas supply unit 40 may be provided to supply the reaction gases into the chamber 10. The reaction gas supply unit 40 may be connected to supply lines that are provided in the upper electrode 28.

The DC power source 34 may be electrically connected to the upper electrode 28 to apply a DC voltage to the upper electrode 28. The DC power source 34 may be a bipolar power source.

The first high frequency power source 30 may be connected to the susceptor 20 (that is, the lower electrode) to apply a first high frequency power. The second high frequency power source 32 may be connected to the susceptor to apply a second high frequency power. That is, two high frequency powers having different frequencies may be applied to the lower electrode 20. The first high frequency power source 30 may apply a high frequency power of 27 MHz to 50 MHz. For example, the first high frequency power source 30 may apply a high frequency power of 40 MHz. The second high frequency power source 32 may apply a high frequency power of 1 to 20 MHz. For example, the second high frequency power source 32 may apply a high frequency power of 13 MHz.

Although it is not illustrated in the figures, first and second RF matchers (not illustrated) may be provided to match internal impedances and load impedances of the first and second high frequency power sources 30, 32. The first and second RF matchers may match the internal impedances and load impedances of the first and second high frequency power sources 30, 32 when plasma is generated in the chamber.

The first high frequency power source 30 may apply a high frequency power with high frequency band of 27 MHz to 50 MHz to the lower electrode, to generate plasma of high density. The DC voltage applied to the upper electrode 28 may be controlled to generate plasma of higher electronic density and uniform plasma density.

The DC power source 34 may apply a DC voltage to the upper electrode 28 to generate electrons. When the DC voltage is applied, the electrons may be accelerated toward the semiconductor substrate (W). The DC power source 34 may apply a voltage of 300V to 1800V (absolute value) to the upper electrode.

The exhaust port 36 may be provided in a lower portion of the chamber 10. An exhaust pump 42 may be provided in the exhaust port 36. By-products may be discharged outside from the chamber 10 through the exhaust port 36. The exhaust pump 42 may pump air out of the chamber 10 to control the pressure of the chamber 10.

The temperature controller 38 may be provided in the sidewall of the chamber 10. The sidewall of the chamber 10 may be maintained at a temperature of 100° C. to 200° C. by the temperature controller 38. The temperature controller 38 may include a heater for increasing the temperature of the sidewall of the chamber 10.

If by-products generated during the etch process were to be adhered to the sidewall of the chamber 10, such by-products could badly affect process reproducibility. Further, by-products adhered to the sidewall of the chamber 10 could act as particles.

However, in this embodiment, the sidewall of the chamber 10 may be maintained at a temperature of 100° C. to 200° C. Accordingly, the adhesion force of the by-products on the sidewall of the chamber 10 may be decreased, and thus, the by-products may be easily discharged from the chamber 10. When the sidewall temperature of the chamber 10 is lower than 100° C., the by-products may be adhered to the sidewall of the chamber 10. When the sidewall temperature of the chamber 10 is higher than 200° C., the sidewall temperature of the chamber 10 may have an effect on the process temperature in the chamber 10.

In this embodiment, two high frequency powers having different frequencies may be applied to the lower electrode 20 to generate plasma of high density. In addition, because the sidewall temperature of the chamber 10 is increased, the by-products may be prevented from being adhered to the sidewall of the chamber 10. Accordingly, the plasma etching apparatus according to an example embodiment may be used to form a contact hole having a higher aspect ratio (for example, an opening having a width of less than 40 nm). In addition, the plasma etching apparatus according to an example embodiment may be used to form a contact hole having an excellent surface roughness.

Further, a temperature rise of the focus ring may be prevented and the focus ring may be maintained at a uniform temperature distribution, to thereby generate plasma of uniform plasma density. Accordingly, contact holes having uniform widths may be formed over the entire region of the substrate.

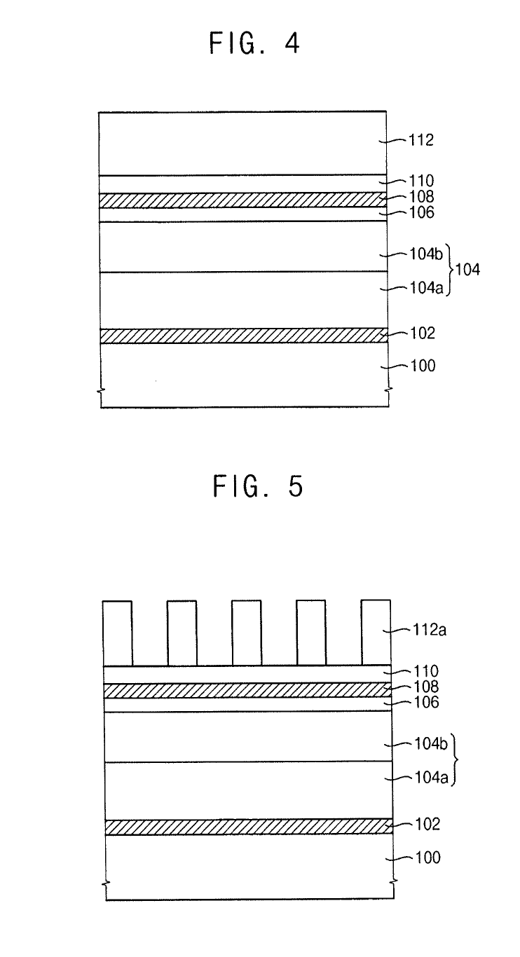

FIGS. 4 to 9 are cross-sectional views illustrating stages of a method of forming a contact hole, in accordance with an example embodiment.

The method of forming a contact hole may be performed using the plasma etching apparatus in FIG. 1.

Referring to FIG. 4, a semiconductor substrate 100 may be prepared to form a contact hole. The semiconductor substrate 100 may be a substrate having a large diameter. For example, the semiconductor substrate 100 may be a 12-inch silicon wafer. A contact region may be formed on the semiconductor substrate 100.

An etch stop layer 102 may be formed on the semiconductor substrate 100. The etch stop layer 102 may be formed using a material having an etch selectivity with respect to an insulation interlayer 104. For example, the etch stop layer 102 may be formed using silicon nitride.

The insulation interlayer 104 may be formed on the etch stop layer 102. The insulation interlayer 104 may include silicon oxide. The material of the insulation interlayer 104 may be selected to form a contact hole having a fine critical dimension (CD). In this embodiment, the material of the insulation interlayer 104 may be selected to form a contact hole having a width less than 40 nm.

The insulation interlayer 104 may include a plurality of different silicon oxide layers stacked on another. For example, the insulation interlayer 104 may include a BPSG (borophosphosilicate glass) layer, an HDP (high density plasma) layer, a TEOS (tetraethyl orthosilicate) layer, an HTO (high temperature oxide) layer, a HARP (high-aspect-ratio process) oxide layer, a SOD (spin on dielectric) layer, etc. For example, after a HARP layer is formed on the substrate, a TEOS layer may be formed on the HARP layer, to form the insulation interlayer 104 including first and second insulation layers 104a and 104b.

An amorphous carbon layer (ACL) 106 may be formed on the insulation interlayer 104. A silicon oxynitride (SiON) layer 108 may be formed on the amorphous carbon layer 106. An anti-reflection coating (ARC) layer 110 may be formed on the silicon oxynitride layer 108. The amorphous carbon layer 106, the silicon oxynitride layer 108 and the anti-reflection coating layer 110 may be used as a mask layer. A photoresist layer 112 may be formed on the anti-reflection coating layer 110.

Referring to FIG. 5, a photolithography process may be performed on the photoresist layer 112 to form a photoresist pattern 112a for forming a contact hole. The photoresist pattern 112a may have an opening with a width less than 40 nm. The openings of the photoresist pattern 112a may expose 10% to 20% of the total an upper surface area of the substrate 100. Although it is not illustrated in the figures, the anti-reflection coating layer 110 may be patterned together when the photoresist layer 112 is patterned.

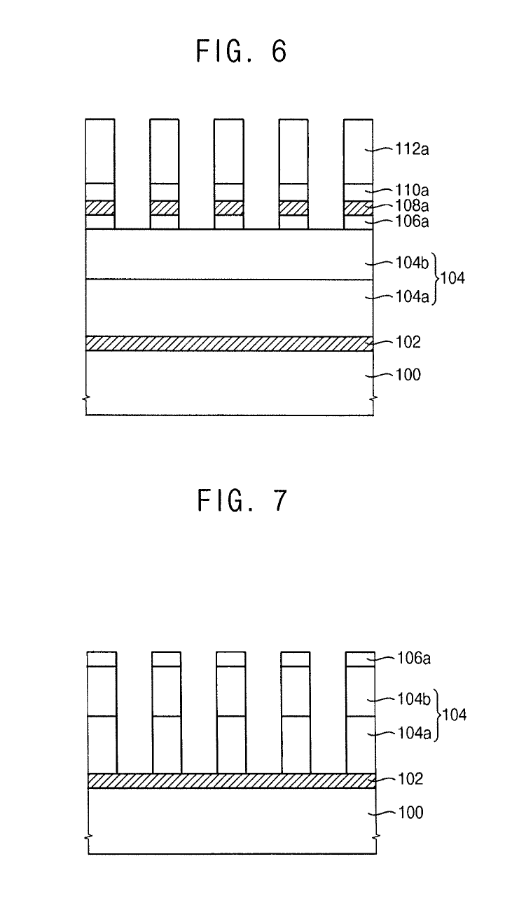

Referring to FIG. 6, the anti-reflection coating layer 110, the silicon oxynitride layer 108 and the amorphous carbon layer 106 may be etched using the photoresist pattern 112a as an etching mask.

In particular, the substrate including the photoresist pattern 112a formed thereon may be loaded into the chamber of the plasma etching apparatus. An etching gas for etching the anti-reflection coating layer 110 and the silicon oxynitride layer 108 and a dilution gas may be supplied to the chamber. The etching gas may be a CFₓ gas or a CₓH_{y}F_{z} gas. For example, the etching gas may be CF₄, CHF₃, CH₂F₂, etc. The dilution gas may be oxygen, nitrogen, hydrogen, CO, CO₃, etc. These may be used alone or in a mixture thereof.

As illustrated in FIG. 1, the first high frequency power source 30 may apply a first high frequency power to the lower electrode 20. The second high frequency power source 32 may apply a second high frequency power to the lower electrode 20. In addition, a DC voltage may be applied to the upper electrode 28. Then, plasma may be generated from the etching gas and the dilution gas supplied to the chamber 10.

The first high frequency power source 30 may apply a high frequency power of 27 MHz to 50 MHz. The second high frequency power source 32 may apply a high frequency power of 1 to 20 MHz. Accordingly, the high frequency powers may be applied to the lower electrode 20.

A DC voltage from several to several thousands of voltages may be applied to the upper electrode 28. For example, a DC voltage of from 300 to 1800 V may be applied to the upper electrode 28. The voltage applied to the upper electrode 28 may be controlled to generate plasma of a desired density.

In the etch process, the plasma density in the chamber 10 may range from 3.0E10 to 13.0E10 cm⁻³. For example, plasma in the chamber 10 may be maintained to have a high plasma density of 12.0E10 to 13.0E10 cm⁻³.

The sidewall of the chamber 10 may be maintained at a temperature above 100° C. For example, the sidewall of the chamber 10 may be maintained at a temperature of 100° C. to 200° C.

In addition, the material of the focus ring provided in the chamber 10 may be selected to increase a heat conductivity of the focus ring, to thereby prevent an unwanted temperature rise of the focus ring. In order to increase the heat conductivity of the focus ring, the focus ring may include a polymer sheet 24b that is attached to a ring 24a of silicon.

The chamber 10 may be maintained under a constant pressure of 1 to 1000 mTorr.

The amorphous carbon layer 106 and the silicon oxynitride 108 may be etched to form an amorphous carbon layer pattern 106a and a silicon oxynitride layer pattern 108a.

Referring to FIG. 7, the insulation interlayer 104 may be etched using the amorphous carbon layer pattern 106a and the silicon oxynitride layer pattern 108a as an etching mask.

An etching gas for etching the insulation interlayer 104 and a dilution gas may be supplied to the chamber. The etching gas may be a CFₓ gas and a CₓH_{y}F_{z} gas. For example, the etching gas may be CF₄, CHF₃, CH₂F₂, etc. The dilution gas may be oxygen, nitrogen, hydrogen, CO, CO₂, etc. These may be used alone or in a mixture thereof. The etching gas and the dilution gas for etching the insulation interlayer 104 may be identical to or different from the etching gas and the dilution gas for etching the amorphous carbon layer 106 and the silicon oxynitride layer 108.

A first high frequency power and a second high frequency power may be applied to the lower electrode 20. A DC voltage may be applied to the upper electrode 28. The first high frequency power, the second high frequency power and the DC voltage at this stage may be substantially the same as in the above-mentioned stage for etching the amorphous carbon layer 106 and the silicon oxynitride layer 108. In other implementations, the first high frequency power, the second high frequency power and the DC voltage in this step may be different from those in the above-mentioned step for etching the amorphous carbon layer 106 and the silicon oxynitride layer 108. The sidewall of the chamber 10 may be maintained at a constant temperature of 100° C. to 200° C.

In the etch process, the plasma density in the chamber 10 may range from 3.0E10 to 13.0E10 cm⁻³. For example, plasma in the chamber 10 may be maintained to have a high plasma density of 12.0E10 to 13.0E10 cm ⁻³.

The insulation interlayer 104 may be etched until an upper surface of the etch stop layer 102 is exposed. Accordingly, the etch stop layer 102 may be used to determine an end point of the etch process.

The above process may be performed on the insulation interlayer 104 to form an opening with a width of 40 nm. The insulation interlayer 104 may be etched using plasma of a high density. Accordingly, an opening having a small width may be precisely formed.

In addition, the sidewall of the chamber 10 may be maintained at a constant temperature of 100° C. to 200° C. Accordingly, by-products generated during the etch process may be prevented from adhering to the sidewall of the chamber 10. Moreover, the by-products may be prevented from acting as particles and badly affecting process reproducibility.

Further, the temperature rise of the focus ring 24 may be prevented during the etch process. Accordingly, contact holes having uniform widths may be formed across the entire region of the substrate. The difference between the widths of the openings in the middle region and peripheral region of the semiconductor substrate may be reduced.

While the insulation interlayer 104 is etched, the photoresist pattern 112a, the anti-reflection coating layer 110a and the silicon oxynitride layer pattern 108 may be removed together from the substrate.

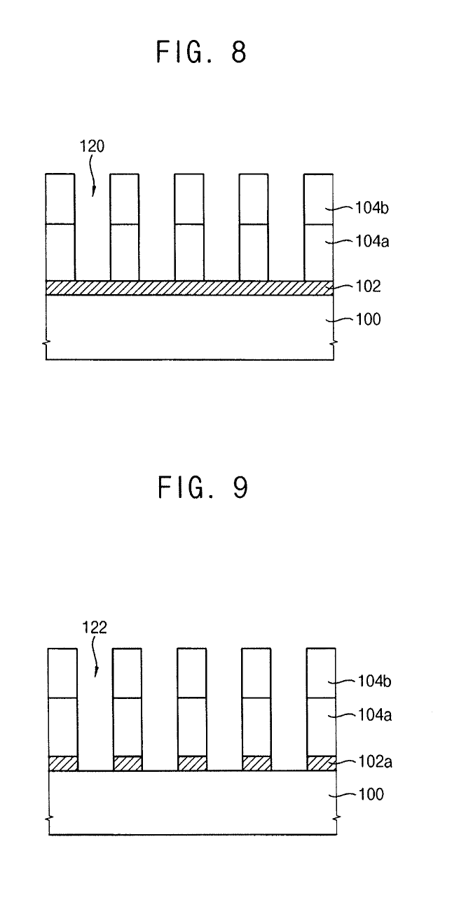

Referring to FIG. 8, an ashing process may be performed to remove the amorphous carbon layer pattern 106a from the chamber 10. In particular, oxygen gas may be supplied to the chamber 10. A first high frequency power and a second high frequency power applied to the lower electrode 20 and a DC voltage applied to the upper electrode 28 in this step may be identical to or different from those in the above-mentioned etching step. The sidewall of the chamber 10 may be maintained at a constant temperature of 100° C. to 200° C.

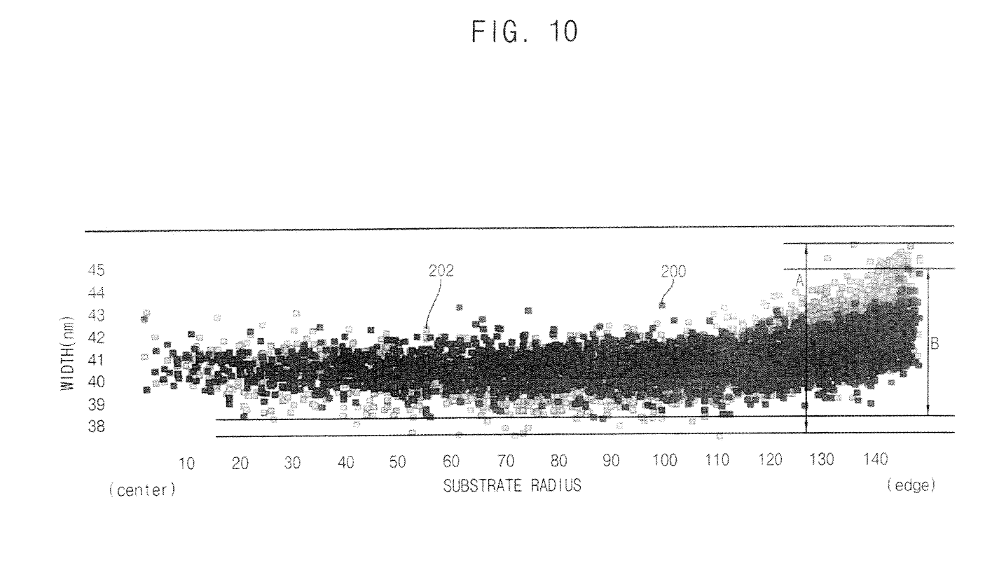

Referring to FIG. 9, the etch stop layer 102 may be etched.

A first high frequency power and a second high frequency power applied to the lower electrode 20 and a DC voltage applied to the upper electrode 28 in this step may be identical to or different from those in the above-mentioned etching step. The sidewall of the chamber 10 may be maintained at a constant temperature of 100° C. to 200° C.

The above processes may be performed to form a contact hole 122 having a small width. The contact hole 122 may be used to form a metal wiring.

### Comparative Experiment

The uniformity of widths of contact holes formed according to an Example Embodiment was compared with the uniformity of widths of contact holes formed according to a Comparative Example.

### Example Embodiment

A 12-inch semiconductor wafer was prepared. The same processes as those explained with reference to FIGS. 4 to 9 were performed to form contact holes.

A first high frequency power of 40 MHz and a second high frequency power of 13 MHz were applied to the lower electrode in the plasma chamber. A DC voltage of 1000 V was applied to the upper electrode. The focus ring in the plasma chamber included a polymer sheet between two rings of silicon. The chamber sidewall was maintained at a temperature of 100° C. Under these etching conditions, the insulation interlayer and the etch stop layer were etched to form a contact hole having a target width of 40 nm. The depth of the contact hole was 2200 Å. The number of the contact holes formed in the semiconductor substrate was 1,000,000. The open ratio of the area of the upper surfaces of the contact holes and the area of the entire upper surface of the semiconductor substrate was 10%.

### Comparative Example

The process conditions in Comparative Example were the same as those in Example Embodiment, except for the conditions of the process of forming contact holes. The contact holes with a target width of 42 nm were formed according to Comparative Example. The depth of the contact hole was 2200 Å.

In Comparative Example, an etching apparatus different from the etching apparatus in FIG. 1 was used to form the contact holes.

Only one high frequency power source was connected to the lower electrode in the plasma chamber. A high frequency power of 13 MHz was applied to the lower electrode in the plasma chamber. In addition, one high frequency power source was connected to the upper electrode. A high frequency power of 60 MHz was applied to the upper electrode in the plasma chamber. A DC voltage was applied to the upper electrode. The focus ring in the plasma chamber included a ring of only silicon. The chamber sidewall was maintained at a temperature of 60° C. Under these etching conditions, the insulation interlayer and the etch stop layer were etched to form a contact hole having a target width of 42 nm.

FIG. 10 is a graph illustrating widths of contact holes versus substrate radius according to Example Embodiment and Comparative Example.

In the Example Embodiment, 3400 contact holes 200 were selected. Widths of the selected contact holes were detected. In FIG. 10, the X axis represents a radial position of a contact hole from the center of the substrate and the Y axis represents a width of the selected contact hole. Thus, the uniformity of widths of contact holes formed according to Example Embodiment was detected.

In the Comparative Example, 3400 contact holes 202 were selected. Widths of the selected contact holes were detected. In FIG. 10, the X axis represents a radial position of a contact hole from the center of the substrate and the Y axis represents a width of the selected contact hole. Thus, the uniformity of widths of contact holes formed according to Comparative Example was detected.

As shown in FIG. 10, the widths of the contact holes 202 of Comparative Example increase gradually toward the peripheral region of the substrate. The difference between the maximum width and the minimum width of the contact holes 202 is about 8 nm.

The widths of the contact holes 200 of Example Embodiment have a lower increasing tendency in the peripheral region of the substrate than those of Comparative Example. The width difference of the contact holes between the middle region and the peripheral region of the substrate is relatively small. The difference between the maximum width and the minimum width of the contact holes 200 is about 5.5 nm.

As a result of the Comparative Experiment, the uniformity of widths of contact holes formed according to the Example Embodiment was found to be higher than the uniformity of widths according to the Comparative Example. Further, according to the Example Embodiment, a contact hole having a width of 40 nm may be reliably formed.

By way of summation and review, as semiconductor devices become highly integrated, wirings included in the semiconductor device have been miniaturized and integrated. In order to form the fine wiring, it may be desirable to form a contact hole having a width of 40 nm. Further, in order to form as many elements on one substrate as possible, it may be desirable that the substrate have a large diameter. When contact holes having a width of 40 nm are formed on a substrate having a large diameter, the number of the contact holes to be formed on the substrate may be greatly increased. Accordingly, it may be difficult to form contact holes having a fine width and a uniform depth. In this case, failures such as not-opening or over-etching of the contact hole may occur frequently, and thus, uniformity of widths of the contact holes in a wafer may be deteriorated.

Example embodiments may advance the art by providing a method of forming contact holes having a fine width, such as a width of less than 40 nm and an excellent surface roughness and by providing a plasma etching apparatus for forming the contact holes. The contact holes formed according to the example embodiments may be used to form metal wirings. Further, the contact holes may be used to form a semiconductor device having high integration and high performance.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A method of forming a contact hole, comprising:
loading a substrate into a plasma chamber, the substrate including an etch stop layer, an insulation interlayer, a mask layer and a photoresist pattern sequentially disposed thereon;
applying a DC voltage to an upper electrode and applying a first high frequency power and a second high frequency power to a lower electrode to generate plasma in the chamber, the first frequency power and second high frequency powers having different frequency levels;
supplying a reaction gas to the chamber to etch the mask layer and the insulation interlayer, wherein the chamber is maintained at a temperature of 100° C. to 200° C.; and
etching the etch stop layer to form the contact hole.

2. The method as claimed in claim 1, wherein a focus ring is provided to surround the substrate loaded in the chamber, the focus ring including a ring of silicon and a polymer sheet.

3. The method as claimed in claim 1, wherein the first high frequency power is 30 MHz to 50 MHz and the second high frequency power is 1 to 20 MHz.

4. The method as claimed in claim 1, wherein the reaction gas for etching the mask layer and the insulation interlayer includes a CFₓ gas or a CₓH_{y}F_{z} gas.

5. The method as claimed in claim 4, wherein the reaction gas for etching the mask layer and the insulation interlayer further includes at least one dilution gas selected from oxygen, nitrogen, hydrogen, CO and CO₂.

6. The method as claimed in claim 1, wherein etching the mask layer and the insulation interlayer includes maintaining the chamber under a pressure of 1 to 1000 mTorr.

7. The method as claimed in claim 1, further comprising performing an ashing process to remove the mask layer after etching the insulation interlayer.

8. The method as claimed in claim 1, wherein etching the mask layer and the insulation interlayer includes maintaining plasma in the chamber to have a plasma density of 3.0E10 to 13.0E10 cm⁻³.

9. The method as claimed in claim 1, wherein etching the mask layer and the insulation interlayer includes applying a DC voltage of 300V to 1800V to the upper electrode.

10. A plasma etching apparatus comprising:
a chamber;
an upper electrode provided in an upper portion of the chamber;
a DC power source connected to the upper electrode;
a gas supply unit configured to supply an etching gas to the chamber;
a lower electrode provided in a lower portion of the chamber under the upper electrode;
a first high frequency power source connected to the lower electrode to apply a first high frequency power;
a second high frequency power source connected to the lower electrode to apply a second high frequency power having a different frequency level from the first high frequency power; and
a temperature controller configured to maintain the chamber at a temperature of 100° C. to 200° C.

11. The plasma etching apparatus as claimed in claim 10, further including a focus ring surrounding a substrate loaded on the lower electrode, the focus ring including a ring of silicon and a polymer sheet.

12. The plasma etching apparatus as claimed in claim 11, wherein the focus ring includes an upper ring of silicon and a lower ring of silicon, and the polymer sheet is between the upper ring and the lower ring.

13. A method of forming contact a hole, the method comprising:
loading a substrate onto a lower electrode inside a plasma chamber such that the substrate is surrounded by a focus ring, the substrate including an etch stop layer, an insulation interlayer, a mask layer and a photoresist pattern sequentially disposed thereon, the photoresist pattern including openings having a width of less than 40 nm, and the focus ring including a ring of silicon and a polymer sheet attached to the ring of silicon; and
carrying out a first etching process to etch the mask layer, the first etching process including:
applying a first DC voltage to an upper electrode and applying a first high frequency power and a second high frequency power simultaneously to the lower electrode to generate plasma in the chamber, the first high frequency power and the second high frequency power having different frequency levels from each other; and
supplying a reaction gas to the chamber to etch the mask layer, using the photoresist pattern as an etching mask of the first etching process, to form a mask layer pattern, while maintaining sidewalls of the chamber at a temperature of 100° C. to 200° C.

14. The method as claimed in claim 13, further including carrying out a second etching process inside the plasma chamber, after the first etching process, the second etching process including:
applying a second DC voltage to the upper electrode and applying a third high frequency power and a fourth high frequency power simultaneously to the lower electrode to generate plasma in the chamber, the third high frequency power and the fourth high frequency power having different frequency levels from each other; and
supplying a reaction gas to the chamber to etch the insulation layer using the mask layer pattern as an etching mask of the second etching process, to form an insulation layer pattern and to remove the photoresist pattern and at least a portion of the mask layer pattern, while maintaining sidewalls of the chamber at a temperature of 100° C. to 200° C.

15. The method as claimed in claim 14, further including carrying out a third etching process inside the plasma chamber, after the second etching process, the third etching process including:
applying a third DC voltage to the upper electrode and applying a fifth high frequency power and a sixth high frequency power simultaneously to the lower electrode to generate plasma in the chamber, the fifth high frequency power and the sixth high frequency power having different frequency levels from each other; and
supplying a reaction gas to the chamber to etch the etch stop layer using the insulation layer pattern as an etching mask of the third etching process, while maintaining sidewalls of the chamber at a temperature of 100° C. to 200° C.

16. The method as claimed in claim 15, wherein,
the mask layer includes an amorphous carbon layer adjacent to the insulation layer and a silicon oxynitride layer on the amorphous carbon layer,
the mask layer pattern formed in the first etching process includes a silicon oxynitride layer pattern and an amorphous carbon layer pattern,
the second etching process removes the oxynitride layer pattern, and
the method further includes an ashing process inside the process chamber after the second etching process and before the third etching process, the ashing process including:
applying a fourth DC voltage to the upper electrode and applying a seventh high frequency power and a eighth high frequency power simultaneously to the lower electrode to generate plasma in the chamber, the seventh high frequency power and the eighth high frequency power having different frequency levels from each other; and
supplying oxygen to the chamber to remove the amorphous carbon layer, while maintaining sidewalls of the chamber at a temperature of 100° C. to 200° C.
